(19) United States
(12) Patent Application Publication
(10) Pub. No.: US 2026/0103430 A1
(43) Pub. Date: Apr. 16, 2026

(54) COATING FOR GRAPHITE VESSELS USED IN MELT INFILTRATION

(71) Applicant: Rolls-Royce High Temperature Composites, Inc., Cypress, CA (US)

(72) Inventors: Timothy Western, Cypress, CA (US); Pathikumar Sellappan, Cypress, CA (US); Kelly Kranjc, Cypress, CA (US); Richard W. Kidd, Cypress, CA (US)

(21) Appl. No.: 18/912,069

(22) Filed: Oct. 10, 2024

(51) Int. Cl. C04B 41/50; C23C 16/32

(52) U.S. Cl. CPC C04B 41/5025; C23C 16/32; C23C 16/325

(57) ABSTRACT

A high temperature vessel includes a structure and a coating. The structure defines a cavity and an interior surface lining the cavity, and includes graphite at the interior surface. The coating overlies at least a portion of the interior surface and defines a contact surface configured to contact molten silicon. The coating includes at least one of silicon carbide or boron carbide, and is deposited via at least one of chemical vapor deposition or chemical vapor infiltration.

### TECHNICAL FIELD

The present disclosure generally relates to melt infiltration.

### BACKGROUND

Silicon melt infiltration can be used to densify a ceramic preform by filling pores of the ceramic preform with molten silicon. For example, a porous ceramic preform may be positioned within a vessel containing molten silicon. The silicon infiltrates pores of the ceramic preform, such as through capillary action, to form an infiltrated ceramic preform. The infiltrated ceramic preform is cooled down to solidify the silicon within the ceramic preform and form a ceramic matrix composite. During infiltration, the silicon may react with portions of the ceramic preform, as well as the vessel holding the ceramic preform.

### SUMMARY

The disclosure describes high temperature graphite vessels for silicon melt infiltration that resists migration of silicon into the graphite vessels. A high temperature vessel includes a graphite structure having an interior surface. The graphite structure includes pores that, if not sealed, may otherwise permit migration of molten silicon and reaction of the molten silicon with carbon to form silicon carbide, resulting in cracking or other damage due to the volume expansion. To protect against this migration and reaction, a coating overlies the interior surface of the graphite structure and defines a contact surface for contacting molten silicon. The coating includes silicon carbide or boron carbide that is deposited via at least one of chemical vapor deposition or chemical vapor infiltration. The coating may be dense, may be continuous, and may extend into pores of the graphite structure to seal the graphite structure from migration of the molten silicon. The protective coating formed using the deposition process is noticeably different than reaction bonded SiC, which is random and also dispersed in molten silicon. In this way, high temperature graphite vessels used for melt infiltration of silicon may have prolonged life.

In some examples, the disclosure describes a high temperature vessel that includes a structure and a coating. The structure defines a cavity and an interior surface lining the cavity, and includes graphite at the interior surface. The coating overlies at least a portion of the interior surface and defines a contact surface configured to contact molten silicon. The coating includes at least one of silicon carbide or boron carbide, and is deposited via at least one of chemical vapor deposition or chemical vapor infiltration.

In some examples, the disclosure describes a method of sealing a structure of a high temperature vessel that includes depositing, via at least one of chemical vapor deposition or chemical vapor infiltration, a coating on an interior surface of the structure. The structure defines a cavity lined by the interior surface and includes graphite at the interior surface. The coating defines a contact surface configured to contact molten silicon and includes at least one of silicon carbide or boron carbide.

In some examples, the disclosure describes a method for fabricating a ceramic matrix composite (CMC) article. The method includes positioning a ceramic preform in a cavity defined by a structure of a high temperature vessel. An interior surface of the structure lines the cavity and includes graphite. The method further includes infiltrating the ceramic preform with molten silicon. A coating overlies at least a portion of the interior surface and defines a contact surface configured to contact the molten silicon. The coating includes at least one of silicon carbide or boron carbide, and is deposited via at least one of chemical vapor deposition or chemical vapor infiltration.

The details of one or more examples are set forth in the accompanying drawings and the description below. Other features, objects, and advantages will be apparent from the description and drawings, and from the claims.

### BRIEF DESCRIPTION OF THE DRAWINGS

FIG. 1A is a block diagram illustrating an example high temperature vessel for silicon melt infiltration.

FIG. 1B is a cross-section side view diagram illustrating the example high temperature vessel of FIG. 1A.

FIG. 2 is a flowchart of an example method for sealing a high temperature vessel.

FIG. 3 is a flowchart of an example method for fabricating a ceramic matrix composite (CMC) article.

### DETAILED DESCRIPTION

The disclosure describes high temperature graphite vessels for silicon melt infiltration that resists migration of silicon into the graphite vessels. High temperature vessels used for melt infiltration, such as crucibles, may be formed from graphite due to its relatively high melting point and resistance to corrosion. However, due to an inherent porosity of graphite and reactivity of graphite with silicon, graphite crucibles may be prone to cracking when used for silicon melt infiltration of ceramic matrix composites (CMCs).

When exposed to molten silicon, silicon may migrate into pores at a surface of the vessel and react with the silicon to form silicon carbide. This reaction may result in a large volume change (e.g., about 300 percent), resulting in cracking. In some instances, a portion of the graphite at the surface of the vessel may react with the silicon to form a silicon carbide layer. However, due to seed-based growth of the silicon carbide, the resulting silicon carbide layer may be isolated, may be discontinuous, and may initiate cracks due to the volume expansion at or near the surface of the vessel. Crucibles may be particularly prone to cracking on first use before such a temporary, discontinuous silicon carbide layer may be formed. While a spray coating, such as boron nitride, applied to the vessel may act as a temporary barrier, eventually molten silicon may penetrate the spray coating.

To reduce infiltration of molten silicon into pores of the graphite structure, a coating overlies the interior surface of the graphite structure and defines a contact surface for contacting molten silicon. The coating includes silicon carbide or boron carbide that is deposited via at least one of chemical vapor deposition (CVD) or chemical vapor infiltration (CVI). In contrast to a discontinuous silicon carbide layer formed in situ on the graphite structure, the applied coating of silicon carbide formed by CVD or CVI may be continuous, dense, and extend into pores of the graphite structure to seal the graphite structure from migration of the molten silicon. For example, a microstructure of the silicon or boron carbide may be carefully controlled to deposit the coating with very low porosity and/or high conformance with the surface of the interior surface, including within pores at the interior surface. In this way, high temperature graphite vessels used for silicon melt infiltration of ceramic matrix composites may have prolonged life.

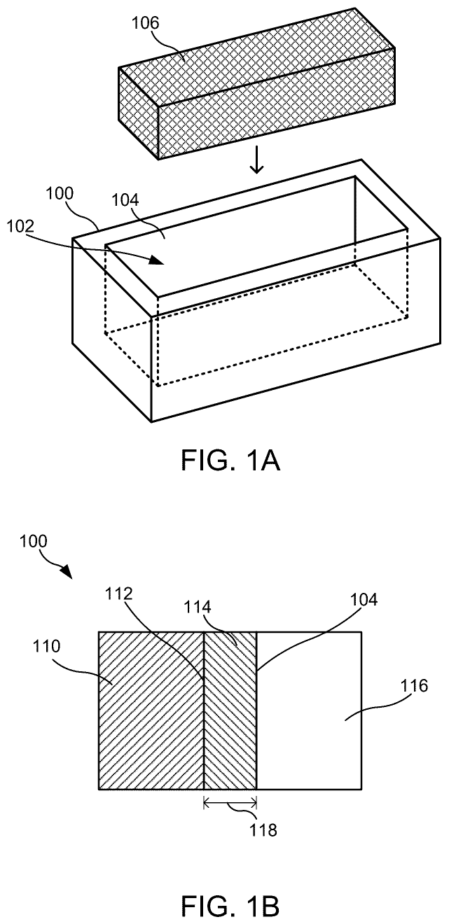

FIG. 1A is a perspective view diagram illustrating an example high temperature vessel 100 for silicon melt infiltration, such as a crucible. Vessel 100 is configured to house a ceramic preform 106 in a cavity 102 and contain molten silicon during infiltration of ceramic preform 106 with the molten silicon. Vessel 100 includes a contact surface 104 configured to contact the molten silicon during infiltration. As such, vessel 100 is configured to be heated to high temperatures, such as temperatures experienced during silicon melt infiltration. For example, vessel 100 may be configured to maintain structural integrity while being heated to a temperature higher than a melting temperature of silicon, remaining at this temperature for an amount of time sufficient to infiltrate ceramic preform 106 with molten silicon, and cooling to a handling temperature. During silicon melt infiltration, molten silicon may infiltrate into pores or voids of ceramic preform 106 to densify ceramic preform 106 and form a ceramic matrix composite (CMC) article. For example, the CMC article may be a component of a gas turbine engine, such as an airfoil.

FIG. 1B is a cross-section side view diagram illustrating the example high temperature vessel 100 of FIG. 1A. Vessel 100 includes a structure 110 defining an interior surface 112 lining cavity 102. Structure 110 includes graphite at interior surface 112. As used herein, graphite includes crystalline carbon arranged in stacked layers of graphene. In some examples, an entirety of structure 110 may be formed from graphite. In other examples, only a portion of structure 110 proximate to interior surface 112 may be formed from graphite. Graphite has good thermal and mechanical properties for melt infiltration processes, including a high melting point (e.g., around 3,500° C.; silicon melt infiltration temperature may exceed about 1,400° C.); good shock resistance, thereby reducing a risk of cracking or breaking during rapid temperature changes; high thermal conductivity for maintaining a relatively uniform temperature; and high strength.

While graphite may have a relatively low porosity compared to amorphous carbon, graphite still may include some porosity that makes it susceptible to migration of and reaction with molten silicon 116. For example, such porosity may result from a layered structure of graphite that includes small gaps or spaces between layers; bonding defects that result in small voids or pores near unbonded particles; and/or crystal defects that create irregularities. As explained above, such pores may permit migration of, and subsequent reaction with, molten silicon 116, resulting in formation of silicon carbide. This silicon carbide may generate stresses due to volumetric expansion, which can result in cracking initiated at the infiltrated pores.

To protect structure 110 from infiltration of molten silicon 116 into pores of structure 110, vessel 100 includes a coating 114. Coating 114 overlies at least a portion of interior surface 112 of structure 110 and defines contact surface 104 configured to contact molten silicon 116. In some examples, a portion of interior surface 112 may correspond to an anticipated contact surface 104 for molten silicon 116. For example, coating 114 may overlie a lower portion of interior surface 112. In some examples, an entirety of interior surface 112, including other surfaces of structure 110. For example, structure 110 may include outer surfaces outside cavity 102 that may be exposed to precursor gases and subsequently coated during a chemical vapor deposition or chemical vapor infiltration process. In such examples, coating 114 may overlie at least 50% of the outer surface.

Coating 114 includes at least one of silicon carbide or boron carbide. Both silicon carbide and boron carbide have high hardness for resisting wear and abrasion; high thermal stability, such as for maintaining structural integrity at temperatures up to about 1600° C.; high chemical resistance to molten silicon 116; and high thermal conductivity. While silicon carbide and boron carbide may have beneficial properties for contacting molten silicon 116, coating 114 formed by a silicon carbide or boron carbide may still be susceptible to migration of molten silicon 116 if coating 114 includes discontinuities, such as pores or cracks. For example, as described above, a layer of silicon carbide may be formed from carbon at a surface portion of structure 110 in situ in the presence of molten silicon 116. However, this in situ layer may not be sufficiently dense and/or continuous to block migration of molten silicon 116 to underlying structure 110, and may be particularly susceptible to fracture in response to degradation of an underlying portion of structure 110. Additionally, an in situ layer produced by reacting silicon with graphite runs the risk of the molten silicon penetrating too far into the porous graphite, expanding on cooling and hence cracking the crucible.

To create a dense coating 114 of silicon carbide and/or boron carbide, coating 114 is deposited via at least one of chemical vapor deposition or chemical vapor infiltration. As described herein, chemical vapor deposition may include a chemical vapor process in which one or more volatile precursors react or decompose on structure 110 to form a thin, dense layer of material. While this dense layer of material may infiltrate into pores of structure 110, the layer may primarily coat interior surface 112 of structure 110 and have limited infiltration into pores. For example, CVD may deposit coating 114 on exposed surfaces of pores, but may not penetrate deeply into the pore structure, such that inner surfaces of the pores may be uncoated. The resulting coating 114 may generally be a thin film that may not fully densify structure 110, depending on the depth of the pores and the ability of the gases to penetrate. However, such coating 114 formed by CVD may still be sufficiently dense to reduce migration of molten silicon 116 into structure 110.

As described herein, chemical vapor infiltration may include a specialized form of chemical vapor deposition designed specifically to impregnate and densify porous substrates, such as structure 110. This chemical vapor process may include introducing precursor gases into the porous material, which infiltrate pores and undergo chemical reactions to deposit the material within the pores. The resulting coating 114 includes a layer of uniform and dense material that extends into pores of structure 110, rather than just near interior surface 112. For example, coating 114 may extend into structure 110 up to a distance of at least about 1 millimeter beyond interior surface 112. The infiltration process can be controlled to achieve different levels of densification, depending on the application requirements.

When deposited through chemical vapor deposition or chemical vapor infiltration, coating 114 has a relatively low porosity. For example, various parameters of the chemical vapor process may be controlled to produce coating 114 having a low porosity including, but not limited to, preparation of interior surface 112 prior to deposition, concentration of the precursor gas, temperature of structure 110, deposition rate of coating 114, pressure, gas flow dynamics of the precursor gas, and any other parameter that may affect a resulting microstructure of coating 114. In some examples, coating 114 may have a low open porosity, such as less than or equal to about 5%. For example, open pores may permit molten silicon 116 to infiltrate through coating 114, such that reducing open porosity, even as closed porosity may remain present, may reduce subsequent reaction of molten silicon 116 with structure 110.

In examples in which coating 114 includes silicon carbide, deposition of coating 114 may be controlled to produce a small average grain size and/or a relatively high proportion of a primary crystal phase. For example, a low average grain size and/or a high volume fraction of a single phase may correspond to a relatively low porosity and/or a more tortuous path for diffusion of silicon. In some examples, an average grain size of the silicon carbide is less than about 5 micrometers. In some examples, the silicon carbide includes a primary phase of greater than or equal to about 90 volume percent (vol. %), in which the primary phase includes at least one of a cubic beta crystal phase or a hexagonal alpha crystal phase. In examples in which coating 114 includes boron carbide, deposition of coating 114 may be controlled to produce a small average grain size. In some examples, an average grain size of the boron carbide is less than about 1 micrometer.

Coating 114 has an average thickness 118 between contact surface 104 and interior surface 112. In some examples, thickness 118 of coating 114 may be sufficiently high to reduce migration through coating 114. For example, coating 114 may still include pores, such as pores that form at grain or crystal boundaries. However, such pores may be less likely to extend through coating 114 as a thickness of coating 114 increases. In some examples, thickness 118 of coating 114 may be sufficiently low to reduce incidence of cracks forming through thermal stresses. For example, silicon carbide may have a CTE between of about 4×10⁻⁶ K⁻¹, while boron carbide may have a CTE of about 5.5×10⁻⁶ K⁻¹. In contrast, graphite may have a CTE of less than about 1×10⁻⁶ K⁻¹ in a direction parallel to the layers of graphite. Thickness 118 of coating 114 is from about 50 micrometers to about 500 micrometers, such as preferably from about 75 micrometers to about 150 micrometers.

While coating 114 is illustrated in FIG. 1B as a single layer, coating 114 may include multiple layers. For example, in examples in which coating 114 is deposited using CVD, coating 114 may include an initial seed layer to create uniform nucleation sites, followed by one or more additional layers overlying the initial seed layer that may progressively seal open pores in underlying layers. As another example, in examples in which coating 114 is deposited using CVI, coating 114 may include one or more interior layers that partially fill pores, followed by one or more layers that form a bulk of coating 114 primarily on interior surface 112 of structure 110.

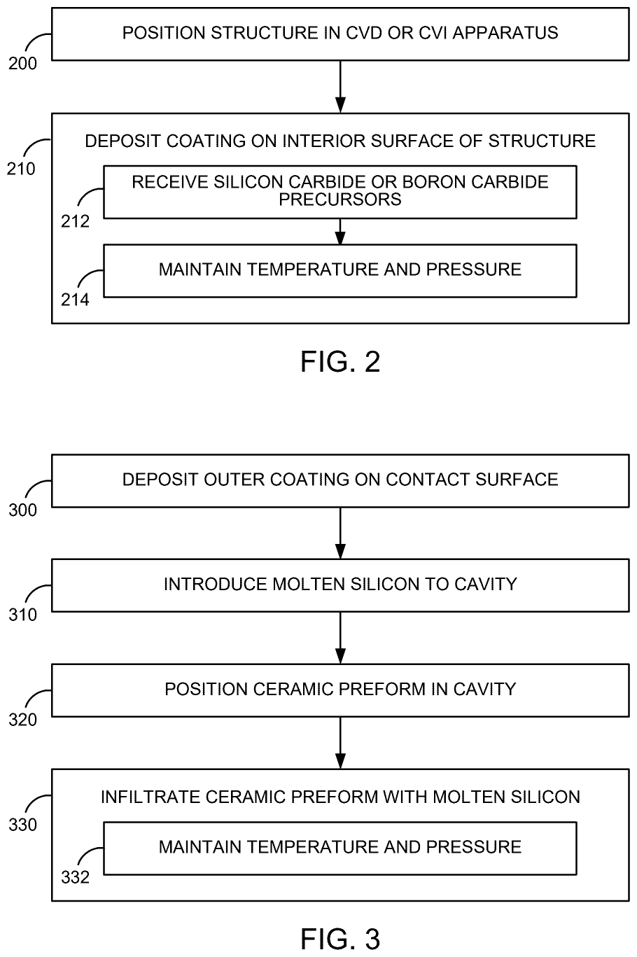

FIG. 2 is a flowchart of an example method for sealing a structure of a high temperature vessel. The method of FIG. 2 will be described with respect to FIG. 1B, but may be used to form other coatings.

The method includes positioning structure 110 in a CVD or CVI apparatus. A CVD or CVI apparatus may include a reactor vessel configured to house substrates, such as structure 110, a heat source configured to heat structure 110 and/or any gases in the reactor vessel, and at least one reactor inlet and outlet for introducing and removing gases, including precursor gases, to and from the reactor vessel. In some examples, interior surface 112 may be prepared prior to deposition of coating 114. For example, interior surface 112 may be surface finished to reduce roughness. In some examples, an entirety of structure 110 may be placed in the CVD or CVI apparatus, such that all exposed surfaces of structure 110 may include coating 114. For example, structure 110 may include an outer surface outside cavity 102 that may receive coating 114.

The method includes depositing, via at least one of chemical vapor deposition or chemical vapor infiltration, coating 114 on interior surface 112 of structure 110 (210). As discussed in FIG. 1B, structure 110 includes graphite at interior surface 112, which may otherwise be susceptible to reacting with molten silicon 116 to a crack-prone silicon carbide layer. Coating 114 defines contact surface 104 configured to contact molten silicon 116. In some examples, coating 114 is deposited on interior surface 112 using chemical vapor deposition. For example, chemical vapor deposition may involve depositing dense layers of silicon carbide or boron carbide on interior surface 112 that results in coating 114 extending across interior surface 112. In some examples, coating 114 is deposited on interior surface 112 using chemical vapor infiltration. For example, chemical vapor infiltration may involve a slower, more gradual formation of coating 114 that results in coating 114 that extends both into pores of structure 110 and across interior surface 112.

Depositing coating 114 on interior surface 112 includes receiving silicon carbide or boron carbide precursors into the CVD or CVI apparatus (212). Silicon carbide precursors may include, but are not limited to, silicon precursors, such as silane, tetramethyl silane, and chlorosilanes; carbon precursors, such as methane, propane, ethylene, and acetylene; combined silicon and carbon precursors, such as methyl trichlorosilane, dimethyldichlorosilane, tetramethyl silane, and hexamethyldisilane. Boron carbide precursors may include, but are not limited to, boron precursors, such as boron trichloride, boron tribromide, boron trifluoride, and boron hydrides; carbon precursors, such as methane, propane, ethylene, and acetylene; and combined boron and carbon precursors, such as trimethyl boron and boron carbide hydrides.

Depositing coating 114 on interior surface 112 further includes maintaining parameters of the chemical vapor process, such as a temperature of structure 110 and a pressure and temperature of gases within the CVD/CVI apparatus (214). For example, various parameters of the chemical vapor process may be controlled to produce coating 114 having a low porosity including, but not limited to, concentration of the precursor gas, temperature of structure 110, deposition rate of coating 114, pressure, gas flow dynamics of the precursor gas, and any other parameter that may affect a resulting microstructure of coating 114. For example, depositing coating 114 may include first depositing a seed layer on interior surface 112 to create a uniform nucleation site. Depositing coating 114 may further including maintaining a slow deposition rate of overlying layers so that the layers grow uniformly, thereby reducing formation of voids that may cause open pores. In the example of chemical vapor infiltration, the deposition rate may be reduced even further to permit deeper infiltration of the precursor gases prior to deposition.

FIG. 3 is a flowchart of an example method for fabricating a ceramic matrix composite (CMC) article. The method of FIG. 3 will be described with respect to FIGS. 1A and 1B, but may be used with other high temperature vessels. In some examples, the method includes depositing an outer coating of boron nitride on contact surface 104 prior to contacting the ceramic preform with molten silicon 116 (300). While the outer coating may not be sufficient on its own to protect structure 110, the outer coating may act as a temporary barrier that reducing migration of molten silicon 116 to coating 114 for additional protection of structure 110. The method includes introducing molten silicon 116 into cavity 102 (310). In some examples, introducing molten silicon 116 may include positioning solid silicon in cavity 102 and heating vessel 100 above a melting point of silicon. In other examples, introducing molten silicon 116 may include pouring molten silicon into cavity 102. Regardless of how silicon is introduced into cavity 102, molten silicon 116 may contact vessel 100 at contact surface 104 of coating 114. The method includes positioning ceramic preform 106 in cavity 102 (320). Ceramic preform 106 may be dipped into molten silicon 116 to substantially submerge portions of ceramic preform for which silicon melt infiltration may be desired. The method includes infiltrating ceramic preform 106 with molten silicon 116 (330). To infiltrate ceramic preform 106, a temperature, and optionally pressure, of molten silicon 116 and vessel 100 may be maintained (332), such that molten silicon 116 remains in a molten state.
Example 1: A high temperature vessel includes a structure defining a cavity and an interior surface lining the cavity; and a coating overlying at least a portion of the interior surface and defining a contact surface configured to contact molten silicon, wherein the structure comprises graphite at the interior surface, wherein the coating comprises at least one of silicon carbide or boron carbide, and wherein the coating is deposited via at least one of chemical vapor deposition or chemical vapor infiltration.
Example 2: The high temperature vessel of example 1, wherein the coating extends into pores of the structure.
Example 3: The high temperature vessel of any of examples 1 and 2, wherein a total porosity of the structure is from about 5 percent (%) to about 30%.
Example 4: The high temperature vessel of any of examples 1 through 3, wherein a thickness of the coating is from about 5 micrometers to about 5 millimeters.
Example 5: The high temperature vessel of any of examples 1 through 4, wherein an open porosity of the coating is less than or equal to about 5%.
Example 6: The high temperature vessel of any of examples 1 through 5, wherein the coating comprises silicon carbide, and wherein an average grain size of the silicon carbide is less than about 5 micrometers.
Example 7: The high temperature vessel of example 6, wherein the silicon carbide comprises a primary phase of greater than or equal to about 90 volume percent (vol. %), and wherein the primary phase comprises at least one of a cubic beta crystal phase or a hexagonal alpha crystal phase.
Example 8: The high temperature vessel of any of examples 1 through 7, wherein the coating comprises boron carbide, and wherein an average grain size of the boron carbide is less than about 1 micrometer.
Example 9: The high temperature vessel of any of examples 1 through 8, wherein the structure comprises an outer surface outside the cavity, and wherein the coating overlies at least 50% of the outer surface.
Example 10: The high temperature vessel of any of examples 1 through 9, wherein the high temperature vessel is a crucible configured to house a ceramic preform in the cavity and infiltrate the ceramic preform with the molten silicon.
Example 11: A method of sealing a structure of a high temperature vessel includes depositing, via at least one of chemical vapor deposition or chemical vapor infiltration, a coating on an interior surface of the structure, wherein the structure defines a cavity lined by the interior surface, wherein the structure comprises graphite at the interior surface, wherein the coating defines a contact surface configured to contact molten silicon, and wherein the coating comprises at least one of silicon carbide or boron carbide.
Example 12: The method of example 11, wherein the coating extends into pores of the structure.
Example 13: The method of any of examples 11 and 12, wherein a total porosity of the structure is from about 5 percent (%) to about 30%.
Example 14: The method of any of examples 11 through 13, wherein a thickness of the coating is from about 5 micrometers to about 5 millimeters.
Example 15: The method of any of examples 11 through 14, wherein an open porosity of the coating is less than or equal to about 5%.
Example 16: The method of any of examples 11 through 15, wherein the coating comprises silicon carbide, and wherein an average grain size of the silicon carbide is less than about 5 micrometers.
Example 17: The method of any of examples 11 through 16, wherein the coating comprises boron carbide, and wherein an average grain size of the boron carbide is less than about 1 micrometer.
Example 18: The method of any of examples 12 through 17, wherein the high temperature vessel is a crucible configured to house a ceramic preform in the cavity and infiltrate the ceramic preform with the molten silicon.
Example 19: A method for fabricating a ceramic matrix composite (CMC) article includes positioning a ceramic preform in a cavity defined by a structure of a high temperature vessel, wherein an interior surface of the structure lines the cavity; and infiltrating the ceramic preform with molten silicon, wherein a coating overlies at least a portion of the interior surface and defines a contact surface configured to contact the molten silicon, wherein the structure comprises graphite at the interior surface, wherein the coating comprises at least one of silicon carbide or boron carbide, and wherein the coating is deposited via at least one of chemical vapor deposition or chemical vapor infiltration.
Example 20: The method of example 19, further comprising depositing an outer coating of boron nitride on the contact surface prior to contacting the ceramic preform with the molten silicon.
Example 21: The method of example 19 or 20, wherein the CMC article is a component of a gas turbine engine.

Various examples have been described. These and other examples are within the scope of the following claims.

What is claimed is:

1. A high temperature vessel, comprising:
a structure defining a cavity and an interior surface lining the cavity; and
a coating overlying at least a portion of the interior surface and defining a contact surface configured to contact molten silicon,
wherein the structure comprises graphite at the interior surface,
wherein the coating comprises at least one of silicon carbide or boron carbide, and
wherein the coating is deposited via at least one of chemical vapor deposition or chemical vapor infiltration.

2. The high temperature vessel of claim 1, wherein the coating extends into pores of the structure.

3. The high temperature vessel of claim 1, wherein a total porosity of the structure is from about 5 percent (%) to about 30%.

4. The high temperature vessel of claim 1, wherein a thickness of the coating is from about 5 micrometers to about 5 millimeters.

5. The high temperature vessel of claim 1, wherein an open porosity of the coating is less than or equal to about 5%.

6. The high temperature vessel of claim 1,
wherein the coating comprises silicon carbide, and
wherein an average grain size of the silicon carbide is less than about 5 micrometers.

7. The high temperature vessel of claim 6,
wherein the silicon carbide comprises a primary phase of greater than or equal to about 90 volume percent (vol. %), and
wherein the primary phase comprises at least one of a cubic beta crystal phase or a hexagonal alpha crystal phase.

8. The high temperature vessel of claim 1,
wherein the coating comprises boron carbide, and
wherein an average grain size of the boron carbide is less than about 1 micrometer.

9. The high temperature vessel of claim 1,
wherein the structure comprises an outer surface outside the cavity, and
wherein the coating overlies at least 50% of the outer surface.

10. The high temperature vessel of claim 1, wherein the high temperature vessel is a crucible configured to house a ceramic preform in the cavity and infiltrate the ceramic preform with the molten silicon to form a ceramic matrix composite (CMC) article.

11. The high temperature vessel of claim 10, wherein the CMC article is a component of a gas turbine engine.

12. A method of sealing a structure of a high temperature vessel, comprising:
depositing, via at least one of chemical vapor deposition or chemical vapor infiltration, a coating on an interior surface of the structure,
wherein the structure defines a cavity lined by the interior surface,
wherein the structure comprises graphite at the interior surface,
wherein the coating defines a contact surface configured to contact molten silicon, and
wherein the coating comprises at least one of silicon carbide or boron carbide.

13. The method of claim 12, wherein the coating extends into pores of the structure.

14. The method of claim 12, wherein a total porosity of the structure is from about 5 percent (%) to about 30%.

15. The method of claim 12, wherein a thickness of the coating is from about 5 micrometers to about 5 millimeters.

16. The method of claim 12, wherein the high temperature vessel is a crucible configured to house a ceramic preform in the cavity and infiltrate the ceramic preform with the molten silicon to form a ceramic matrix composite (CMC) article.

17. The method of claim 16, wherein the CMC article is a component of a gas turbine engine.

18. A method for fabricating a ceramic matrix composite (CMC) article, comprising:
positioning a ceramic preform in a cavity defined by a structure of a high temperature vessel, wherein an interior surface of the structure lines the cavity; and
infiltrating the ceramic preform with molten silicon,
wherein a coating overlies at least a portion of the interior surface and defines a contact surface configured to contact the molten silicon,
wherein the structure comprises graphite at the interior surface,
wherein the coating comprises at least one of silicon carbide or boron carbide, and
wherein the coating is deposited via at least one of chemical vapor deposition or chemical vapor infiltration.

19. The method of claim 18, further comprising depositing an outer coating of boron nitride on the contact surface prior to contacting the ceramic preform with the molten silicon.

20. The method of claim 18, wherein the CMC article is a component of a gas turbine engine.
